(19) United States
(12) Patent Application Publication
(10) Pub. No.: US 2012/0175152 A1
(43) Pub. Date: Jul. 12, 2012

(54) HIGH-SPEED SIGNAL TRANSMISSION BOARD

(75) Inventors: Kazuhiro Mizukami, Tokyo (JP); Toshihiro Kusagaya, Tokyo (JP)

(73) Assignee: FUJITSU COMPONENT LIMITED, Tokyo (JP)

(21) Appl. No.: 13/329,549

(22) Filed: Dec. 19, 2011

(30) Foreign Application Priority Data
Jan. 6, 2011 (JP) 2011-001047

(51) Int. Cl. H05K 1/11; H05K 1/02

(52) U.S. Cl. 174/251

(57) ABSTRACT

A high-speed signal transmission board includes a first board part including a first ground pattern, a first insulating layer formed on a first surface and a second surface of the first ground pattern, and a first electrically conductive pattern formed on a surface of the first insulating layer; a second board part including a second ground pattern, a second insulating layer formed on a first surface and a second surface of the second ground pattern, and a second electrically conductive pattern formed on a surface of the second insulating layer; and a connecting part connecting the first electrically conductive pattern of the first board part and the second electrically conductive pattern of the second board part with the first board part and the second board part facing each other.

### CROSS-REFERENCE TO RELATED APPLICATION

The present application is based upon and claims the benefit of priority of Japanese Patent Application No. 2011-001047, filed on Jan. 6, 2011, the entire contents of which are incorporated herein by reference.

### BACKGROUND OF THE INVENTION

1. Field of the Invention

The present invention relates to a high-speed signal transmission board for transmitting a high-speed signal.

2. Description of the Related Art

A conventional board is known that includes at least a first board having at least a signal electrode and a pair of first ground electrodes provided parallel to and across the signal electrode from each other; a second board having a pair of second ground electrodes provided at positions corresponding to the first ground electrodes; and an electric conductor connecting the first ground electrodes of the first board and the second ground electrodes of the second board, where a space part is defined by the electric conductor around the signal electrode. (See, for example, Japanese Laid-Open Patent Application No. 2007-27172.)

### SUMMARY OF THE INVENTION

According to an aspect of the invention, a high-speed signal transmission board includes a first board part including a first ground pattern, a first insulating layer formed on a first surface and a second surface of the first ground pattern, and a first electrically conductive pattern formed on a surface of the first insulating layer; a second board part including a second ground pattern, a second insulating layer formed on a first surface and a second surface of the second ground pattern, and a second electrically conductive pattern formed on a surface of the second insulating layer; and a connecting part connecting the first electrically conductive pattern of the first board part and the second electrically conductive pattern of the second board part with the first board part and the second board part facing each other.

The object and advantages of the embodiments will be realized and attained by means of the elements and combinations particularly pointed out in the claims.

It is to be understood that both the foregoing general description and the following detailed description are exemplary and explanatory and not restrictive of the invention as claimed.

### BRIEF DESCRIPTION OF THE DRAWINGS

Other objects, features and advantages of the present invention will become more apparent from the following detailed description when read in conjunction with the accompanying drawings, in which:

FIG. 1 is a cross-sectional view of part of a high-speed transmission board according to a first embodiment;

FIG. 2A is a perspective view illustrating interconnects covered with insulating layers included in FR4 boards on both sides, and FIG. 2B is a perspective view illustrating interconnects formed on an insulating layer included in an FR4 board and having their upper surfaces exposed to air;

FIGS. 3A and 3B are graphs illustrating simulation results of determining the transmission loss of signals in the interconnects illustrated in FIGS. 2A and 2B, respectively; and

FIG. 4 is a cross-sectional view of part of a high-speed transmission board according to a second embodiment.

### DETAILED DESCRIPTION OF THE PREFERRED EMBODIMENTS

In the conventional board, such as the board described in Japanese Laid-Open Patent Application No. 2007-27172, a signal electrode, an electric conductor, and ground electrodes are electrically insulated by a common air layer (space part), so that a signal may be degraded to affect high-speed signal transmission.

According to an aspect of the present invention, a high-speed signal transmission board is provided that has good signal propagation characteristics at high speed.

A description is given below, with reference to the accompanying drawings, of embodiments to which a high-speed signal transmission board according to an aspect of the present invention is applied.

### [a] First Embodiment

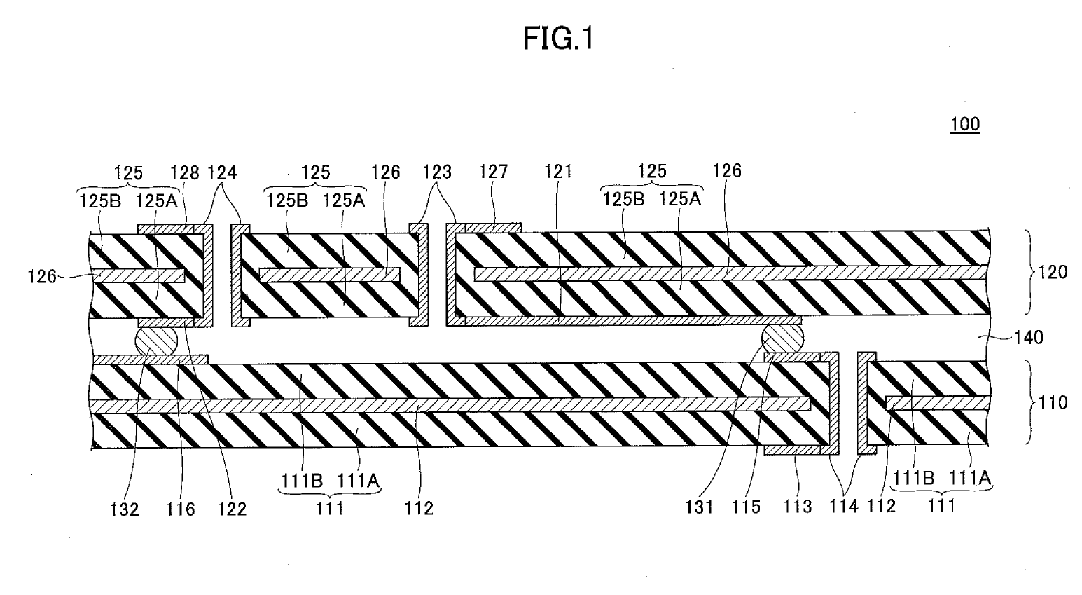

FIG. 1 is a cross-sectional view of part of a high-speed transmission board 100 according to a first embodiment.

The high-speed signal transmission board 100 includes a first board part 110 and a second board part 120. The first board part 110 and the second board part 120 are connected by connecting parts 131 and 132 to face each other across a space (space part) 140.

The first board part 110 includes an insulating layer 111, a ground pattern 112, an interconnect pattern 113, a via 114, an interconnect pattern 115, and an interconnect pattern 116.

The second board part 120 includes an interconnect pattern 121, an interconnect pattern 122, a via 123, a via 124, an insulating layer 125, a ground pattern 126, an interconnect pattern 127, and an interconnect pattern 128.

Each of the first board part 110 and the second board part 120 of the high-speed signal transmission board 100 according to the first embodiment is, for example, a multilayer board formed of, for example, an FR4 (Flame Retardant Type 4) board.

Here, the cross section illustrated in FIG. 1 is the cross section of part of the high-speed signal transmission board 100 of the first embodiment. The first board part 110 and the second board part 120 of the high-speed signal transmission board 100 of the first embodiment may include more interconnect patterns, vias, and/or ground patterns.

Further, the two connecting parts 131 and 132 are illustrated in FIG. 1, but the high-speed signal transmission board 100 of the first embodiment may include more connecting parts.

The first board part 110 and the second board 120 are connected by the connecting parts 131 and 132 to have a uniform interval (distance) between the first board part 110 and the second board part 120.

The insulating layer 111 includes two layers: an insulating layer 111A and an insulating layer 111B. The ground pattern 112 is formed between the insulating layer 111A and the insulating layer 111B. That is, the insulating layer 111A and the insulating layer 111B are formed one on each side (surface) of the ground pattern 112.

The insulating layer 111 is formed by, for example, forming the ground pattern 112 on one surface (the lower surface in FIG. 1) of the insulating layer 111B and thereafter forming the insulating layer 111A.

In FIG. 1, no boundary is illustrated between the insulating layer 111A and the insulating layer 111B, but the lower half of the insulating layer 111 is the insulating layer 111A and the upper half of the insulating layer 111 is the insulating layer 111B with the ground pattern 112 serving as a boundary.

The ground pattern 112 is maintained at ground potential, and serves as a return-side pattern for a high-speed signal. The ground pattern 112 is formed of, for example, copper foil. The ground pattern 112 is provided for good impedance matching with the interconnect patterns 113, 115, 116, 121, and 122 to provide good propagation characteristics for signals transmitted in the interconnect patterns 113, 115, 116, 121, and 122.

The interconnect pattern 113 is formed on the surface (the lower surface in FIG. 1) of the insulating layer 111A to be connected to the interconnect pattern 115 by way of the via 114. The interconnect pattern 113 is formed on the surface (the lower surface in FIG. 1) of the high-speed signal transmission board 100. For example, electronic components such as a large scale integrated circuit (LSI), a chip, a resistor, and a capacitor are connected to the interconnect pattern 113. The interconnect pattern 113 is formed of, for example, copper foil.

The via 114 is provided to ensure a connection between layers. The via 114 is provided through the insulating layers 111A and 111E in the directions of the thickness of the insulating layers 111A and 111E (the layer thickness directions), being insulated from the ground pattern 112. The via 114 is formed of, for example, copper.

The interconnect pattern 115 is formed on the surface (the upper surface in FIG. 1) of the insulating layer 111B. The via 114 and the connecting part 131 are connected to the interconnect pattern 115. The upper surface of the interconnect pattern 115 is exposed to the space 140. The interconnect pattern 115 is formed of, for example, copper foil.

The interconnect pattern 116 is formed on the surface (the upper surface in FIG. 1) of the insulating layer 111B. The connecting part 132 is connected to the upper surface of the interconnect pattern 116. The upper surface of the interconnect pattern 116 is exposed to the space 140. The interconnect pattern 116 is formed of, for example, copper foil.

The insulating layer 125 includes two layers: an insulating layer 125A and an insulating layer 125B. The ground pattern 126 is formed between the insulating layer 125A and the insulating layer 125B. That is, the insulating layer 125A and the insulating layer 125B are formed one on each side (surface) of the ground pattern 126.

The insulating layer 125 is formed by, for example, forming the ground pattern 126 on one surface (the lower surface in FIG. 1) of the insulating layer 125B and thereafter forming the insulating layer 125A.

In FIG. 1, no boundary is illustrated between the insulating layer 125A and the insulating layer 125B, but the lower half of the insulating layer 125 is the insulating layer 125A and the upper half of the insulating layer 125 is the insulating layer 125B with the ground pattern 126 serving as a boundary.

The ground pattern 126 is maintained at ground potential, and serves as a return-side pattern for a high-speed signal. The ground pattern 126 is formed of, for example, copper foil. The ground pattern 126 is provided for good impedance matching with the interconnect patterns 115, 116, 121, 122, 127, and 128 to provide good propagation characteristics for signals transmitted in the interconnect patterns 115, 116, 121, 122, 127, and 128.

The interconnect pattern 121 is formed on the surface (the lower surface in FIG. 1) of the insulating layer 125A to be connected to the connecting part 131 and the via 123. The lower surface of the interconnect pattern 121 is exposed to the space 140. The interconnect pattern 121 is formed of, for example, copper foil.

The interconnect pattern 122 is formed on the surface (the lower surface in FIG. 1) of the insulating layer 125A to be connected to the connecting part 132 and the via 124. The lower surface of the interconnect pattern 122 is exposed to the space 140. The interconnect pattern 122 is formed of, for example, copper foil.

The via 123 is provided to ensure a connection between layers. The via 123 is provided through the insulating layers 125A and 125B in the directions of the thickness of the insulating layers 125A and 125B (the layer thickness directions), being insulated from the ground pattern 126. The via 123 is formed of, for example, copper.

The via 124 is provided to ensure a connection between layers. The via 124 is provided through the insulating layers 125A and 125B in the directions of the thickness of the insulating layers 125A and 125B, being insulated from the ground pattern 126. The via 124 is formed of, for example, copper.

The interconnect pattern 127 is formed on the surface (the upper surface in FIG. 1) of the insulating layer 125B to be connected to the interconnect pattern 121 by way of the via 123. The interconnect pattern 127 is formed on the surface (the upper surface in FIG. 1) of the high-speed signal transmission board 100. For example, electronic components such as a large scale integrated circuit (LSI), a chip, a resistor, and a capacitor are connected to the interconnect pattern 127. The interconnect pattern 127 is formed of, for example, copper foil.

The interconnect pattern 128 is formed on the surface (the upper surface in FIG. 1) of the insulating layer 125B to be connected to the interconnect pattern 122 by way of the via 124. The interconnect pattern 128 is formed on the surface (the upper surface in FIG. 1) of the high-speed signal transmission board 100. For example, electronic components such as a large scale integrated circuit (LSI), a chip, a resistor, and a capacitor are connected to the interconnect pattern 128. The interconnect pattern 128 is formed of, for example, copper foil.

The connecting part 131 is provided to ensure an electrical connection between the interconnect pattern 115 and the interconnect pattern 121 as well as to fix the first board part 110 including the interconnect pattern 115 and the second board part 120 including the interconnect pattern 121 to each other. The connecting part 131 is formed of, for example, an electrically conductive adhesive agent or solder.

The connecting part 132 is provided to ensure an electrical connection between the interconnect pattern 116 and the interconnect pattern 122 as well as to fix the first board part 110 including the interconnect pattern 116 and the second board part 120 including the interconnect pattern 122 to each other. The connecting part 132 is formed of, for example, an electrically conductive adhesive agent or solder.

The first board part 110 and the second board part 120 are connected by the connecting parts 131 and 132 to be across (separated by) the space 140 from each other with a uniform interval (distance) between the first board part 110 and the second board part 120.

In the high-speed signal transmission board 100 as described above, the interconnect patterns 115, 116, 121, and 122 have their surfaces exposed to air because of the space 140.

Here, the ratio of the permittivity of air to the permittivity of the insulating layers 111 and 125 included in the FR4 boards is 1:4. The transmission loss of a high-speed signal is proportional to the square root of permittivity. Therefore, the transmission loss of an interconnect pattern exposed to air on both sides is the half of the transmission loss of an interconnect pattern covered with FR4 insulating layers on both sides.

The interconnect patterns 115, 116, 121, and 122 have their respective surfaces on one side exposed to air because of the space 140 while being inside (between layers in) the high-speed signal transmission board 100.

Therefore, transmission loss in the interconnect patterns 115, 116, 121, and 122 is reduced to two-thirds (⅔=1/(1.5)) of transmission loss in an interconnect pattern covered with insulating layers on both sides.

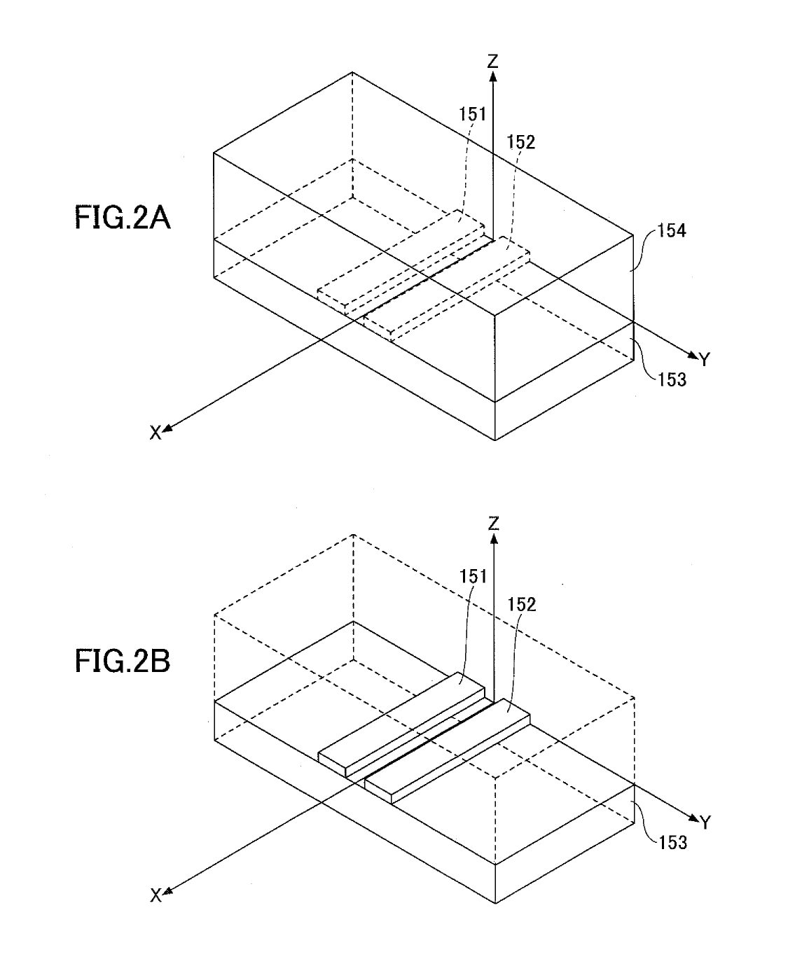

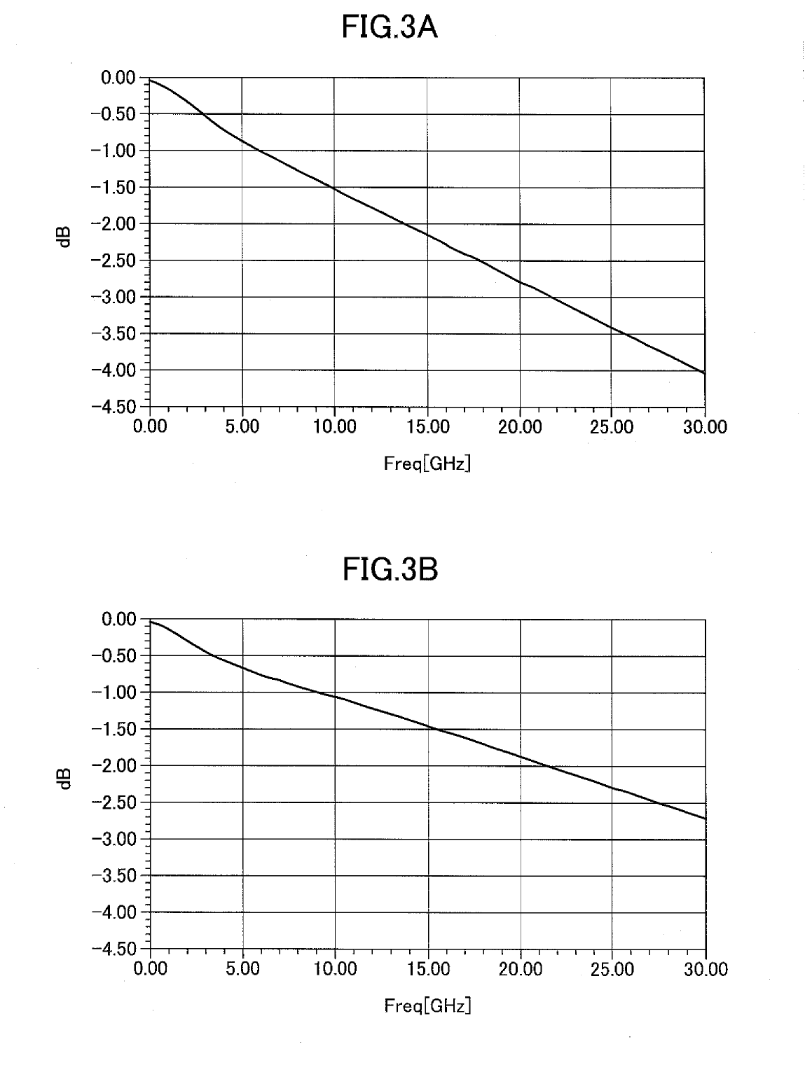

Here, a description is given, using FIGS. 2A and 2B and FIGS. 3A and 3B, of simulation results of determining transmission loss in interconnects covered with insulating layers included in FR4 boards on both sides and in interconnects formed on an insulating layer included in an FR4 substrate and having their upper surfaces exposed to air.

FIG. 2A is a perspective view illustrating interconnects covered with insulating layers included in FR4 boards on both sides. FIG. 2B is a perspective view illustrating interconnects formed on an insulating layer included in an FR4 board and having their upper surfaces exposed to air.

Interconnects 151 and 152 illustrated in FIGS. 2A and 2B transmit differential high-speed signals (a positive [+] high-speed signal and a negative [−] high-speed signal).

Referring to FIG. 2A, the interconnects 151 and 152 are formed on an insulating layer 153 and have their upper surfaces covered with an insulating layer 154.

Referring to FIG. 2B, the interconnects 151 and 152 are formed on the insulating layer 153 and have their upper surfaces exposed to air.

As illustrated in FIGS. 2A and 2B, the x-axis, the y-axis, and the z-axis are defined, and the interconnects 151 and 152 are so disposed as to be parallel to the x-axis and have the x-axis passing (extending) between the interconnects 151 and 152.

FIGS. 3A and 3B are graphs illustrating simulation results of determining the transmission loss of signals in the interconnects 151 and 152 illustrated in FIGS. 2A and 2B, respectively.

A high frequency structure simulator (HFSS) is used for the simulations.

As illustrated in FIG. 3A, in the case where the interconnects 151 and 152 have their upper surfaces covered with the insulating layer 154, the transmission loss is approximately −1.51 dB when the frequency of a high-speed signal presented in the interconnect 151 is 10 GHz, and is approximately −2.79 dB when the frequency of the high-speed signal presented in the interconnect 151 is 20 GHz.

Further, as illustrated in FIG. 3B, in the case where the interconnects 151 and 152 have their upper surfaces exposed to air, the transmission loss is approximately −1.07 dB when the frequency of a high-speed signal presented in the interconnect 151 is 10 GHz, and is approximately −1.88 dB when the frequency of the high-speed signal presented in the interconnect 151 is 20 GHz.

It is found from these results that transmission loss in the interconnects 151 and 152 illustrated in FIG. 2B, whose upper halves are exposed to air, is reduced to two-thirds of transmission loss in the interconnects 151 and 152 illustrated in FIG. 2A, whose upper halves are covered with the insulating layer 154.

As a result, it is found that transmission loss in the interconnects 115, 116, 121, and 122 is reduced to two-thirds (⅔=1/(1.5)) of transmission loss in an interconnect pattern covered with insulating layers on both sides.

Further, the interconnect patterns 115 and 116 and the interconnect patterns 121 and 122 are isolated from the ground patterns 112 and 126 by the insulating layers 111 and 125, respectively.

Therefore, signals are less likely to be degraded in the interconnect patterns 115, 116, 121, and 122, so that it is possible to have good signal propagation characteristics at high speed.

Further, in the high-speed signal transmission board 100 of the first embodiment, the interval (distance) between the first board part 110 and the second board part 120 is kept uniform (fixed) by the connecting parts 131 and 132.

Therefore, the distance between any of the interconnect patterns 113, 115, and 116 and the ground pattern 126 in the layer thickness directions is kept uniform, and the distance between any of the interconnect patterns 121, 122, 127, and 128 and the ground pattern 112 in the layer thickness directions is kept uniform.

Thus, the interval between the ground pattern 126, maintained at ground potential, and any of the interconnect patterns 113, 115, and 116, in which high-speed signals are transmitted, in the layer thickness directions is uniform, and the interval between the ground pattern 112, maintained at ground potential, and any of the interconnect patterns 121, 122, 127, and 128, in which high-speed signals are transmitted, in the layer thickness directions is uniform.

Therefore, in the high-speed signal transmission board 100 of the first embodiment, it is possible to control variations in characteristic impedance and the occurrence of impedance mismatching in the interconnect patterns 113, 115, 116, 121, 122, 127, and 128.

Further, this makes it possible to provide the high-speed signal transmission board 100, which controls signal degradation and an increase in transmission loss and has good signal propagation characteristics at high speed.

Thus, according to the high-speed signal transmission board 100 of the first embodiment, the surfaces of the interconnect patterns 115, 116, 121, and 122 on one side are exposed to air, so that it is possible to reduce signal transmission loss, and the interconnect patterns 115 and 116 and the interconnect patterns 121 and 122 are isolated from the ground pattern 112 and the ground pattern 126 by the insulating layer 111 and the insulating layer 125, respectively, so that it is possible to have good signal propagation characteristics at high speed in the interconnect patterns 115, 116, 121, and 122.

Further, the interval between the first board part 110 and the second board part 120 is kept uniform by the connecting parts 131 and 132, so that it is possible to control variations in characteristic impedance and the occurrence of impedance mismatching in the interconnect patterns 113, 115, 116, 121, 122, 127, and 128.

As a result, it is possible to provide the high-speed signal transmission board 100, which controls signal degradation and an increase in transmission loss and has good signal propagation characteristics at high speed.

### [b] Second Embodiment

A high-speed signal transmission board 200 according to a second embodiment is different from the high-speed transmission board 100 of the first embodiment in having intermediate insulating layers, in addition to the connecting parts 131 and 132, as a member that connects the first board part 110 and the second board part 120.

In the following, the same elements as or elements equal to those of the high-speed transmission board 100 of the first embodiment are referred to by the same reference numerals, and a description thereof is omitted.

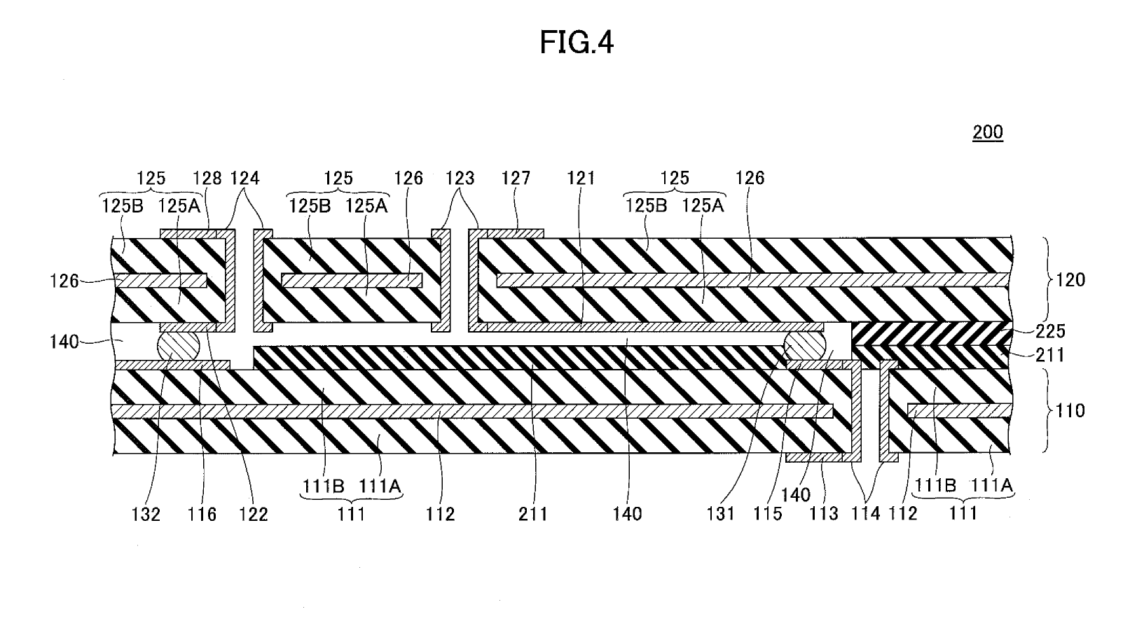

FIG. 4 is a cross-sectional view of part of the high-speed transmission board 200 of the second embodiment.

The high-speed transmission board 200 of the second embodiment is formed by inserting intermediate insulating layers 211 and 225 into part of the space 140 between the first board part 110 and the second board part 120 of the high-speed transmission board 100 of the first embodiment.

The intermediate insulating layer 211 is formed to cover part of the insulating layer 111B, part of the interconnect pattern 115, and part of the surface (the upper surface in FIG. 4) of the via 114 of the first board part 110.

The intermediate insulating layer 225 is formed to cover part of the surface (the upper lower surface in FIG. 4) of the insulating layer 125A of the second board part 120.

The thickness of each of the intermediate insulating layers 211 and 225 is determined to be the half of the dimension of the space 140 in the layer thickness directions. As illustrated on the right end side in FIG. 4, the intermediate insulating layers 211 and 215 are bonded with an adhesive agent or the like where the intermediate insulating layers 211 and 215 are stacked, so as to fix the first board part 110 and the second board part 120.

As illustrated in the first embodiment using FIGS. 2A and 2B and FIGS. 3A and 3B, signal transmission loss is lower when the upper surface of an interconnect is exposed to air than when the upper surface of the interconnect is covered with an insulating layer.

Therefore, it is preferable that the intermediate insulating layers 211 and 225 be so formed as to minimize portions of the upper surfaces of the interconnect patterns 115, 116, 121, and 122 facing on the space 140, which portions are covered with the intermediate insulating layers 211 and 225.

For example, the intermediate insulating layer 211, which covers part of the upper surface of the via 114 in FIG. 4, may also be formed without covering the upper surface of the via 114.

Thus, according to the high-speed transmission board 200 of the second embodiment, it is possible to connect the first board part 110 and the second board part 120 by the intermediate insulating layers 211 and 225 as well as the connecting parts 131 and 132. Therefore, it is possible to increase the joining strength of the first board part 110 and the second board part 120 compared with the high-speed transmission board 100 of the first embodiment.

Thus, according to the second embodiment, it is possible to provide the high-speed signal transmission board 200, which controls signal degradation and an increase in transmission loss, has good signal propagation characteristics at high speed, and is increased in the joining strength of the first board part 110 and the second board part 120.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that various changes, substitutions, and alterations could be made hereto without departing from the spirit and scope of the invention.

What is claimed is:

1. A high-speed signal transmission board, comprising:
a first board part including a first ground pattern, a first insulating layer formed on a first surface and a second surface of the first ground pattern, and a first electrically conductive pattern formed on a surface of the first insulating layer;
a second board part including a second ground pattern, a second insulating layer formed on a first surface and a second surface of the second ground pattern, and a second electrically conductive pattern formed on a surface of the second insulating layer; and
a connecting part connecting the first electrically conductive pattern of the first board part and the second electrically conductive pattern of the second board part with the first board part and the second board part facing each other.

2. The high-speed signal transmission board as claimed in claim 1, wherein an interval between the first board part and the second board part is kept uniform by the connecting part.

3. The high-speed signal transmission board as claimed in claim 1, further comprising:
an intermediate insulating layer formed between a part of the surface of the first insulating layer in which part the first electrically conductive pattern is absent and a part of the surface of the second insulating layer in which part the second electrically conductive pattern is absent in a space between the first board part and the second board part.

4. The high-speed signal transmission board as claimed in claim 3, wherein the intermediate insulating layer includes a first portion formed on the part of the surface of the first insulating layer and a second portion formed on the part of the surface of the second insulating layer, the first portion and the second portion being bonded with an adhesive agent where the first portion and the second portion are stacked in layers.

5. The high-speed signal transmission board as claimed in claim 1, further comprising at least one of:
a first via provided through the first insulating layer and having an end connected to the first electrically conductive pattern, the first via being electrically insulated from the first ground pattern; and
a second via provided through the second insulating layer and having an end connected to the second electrically conductive pattern, the second via being electrically insulated from the second ground pattern.

6. The high-speed signal transmission board as claimed in claim 1, wherein the connecting part is one of solder and an electrically conductive adhesive agent.
